(19) United States
(12) Patent Application Publication
(10) Pub. No.: US 2010/0232117 A1
(43) Pub. Date: Sep. 16, 2010

(54) CAR AUDIO SYSTEM

(75) Inventor: Seongho Yoon, Seoul (KR)

Correspondence Address: HAMRE, SCHUMANN, MUELLER & LARSON, P.C., P.O. BOX 2902, MINNEAPOLIS, MN, 55402-0902, US

(73) Assignee: NAMSUNG CO., LTD., Seoul (KR)

(21) Appl. No.: 12/551,954

(22) Filed: Sep. 1, 2009

(30) Foreign Application Priority Data
Mar. 13, 2009 (KR) 10-2009-0021832

(51) Int. Cl. H05K 7/16

(52) U.S. Cl. 361/725

(57) ABSTRACT

The present invention relates to a car audio system, in which a front panel is rotatably provided on the front of a car audio main body and a stand is provided on the rear of the front panel to place a portable media device. According to the present invention, when the front panel is opened such that the rear races the front side, the stand is exposed, such that the portable media device can be placed on the stand and easily used in a vehicle.

### RELATED APPLICATIONS

The present application claims priority to Korean Patent Application Serial Number 10-2009-0021832, filed on Mar. 13, 2009, the entirety of which is hereby incorporated by reference.

### BACKGROUND OF THE INVENTION

1. Field of the Invention

The present invention relates to a car audio system, particularly designed to simply place and use a variety of portable media devices in a vehicle.

2. Description of the Related Art

Car audio systems are audio devices mounted in a vehicle, and are generally mounted in the middle of the instrument panel, that is, between the driver's seat and the passenger's seat in a vehicle.

Typical car audio systems are devices which includes a deck where audio media, such as a compact disc or a cassette tape, is inserted, an operation panel at the front for a user to operate, and a display panel that allows the user to see the operational state operated by the operation panel, and play songs and music in a vehicle by operating the existing audio medium, such as compact discs and cassette tapes, in the deck.

In recent years, with the spread of portable media devices, such as MP3 players, portable multimedia players (hereafter, referred to as ‘PMP’), etc., the use of existing audio media, such as compact discs and cassette tapes, has rapidly reduced.

Accordingly, people who would rather charge and use their own portable media devices in vehicles have increased, than use the existing audio medium, such as compact discs or cassette tapes in vehicles.

### SUMMARY OF THE INVENTION

However, car audio systems in the related art are designed to operate the existing voice media, such as compact disc players for music or cassette tape players, such that there is a problem in that it is impossible to connect portable media devices, which has been recently popularized.

Since specific devices are necessary to use portable media device in a vehicle, cost is increased due to purchasing required specific devices.

Further, the specific devices for the portable media devices complicate and mess up the narrow interior of a vehicle, which spoils the appearances and interferes with safe driving.

In particular, PMPs can play not only voices, but videos, such that it makes it possible to watch images, such as movies; however, it is difficult to place PMPs in a vehicle, such that it is substantially difficult to perform the video function in a vehicle that is traveling.

It is an object of the present invention to provide a car audio system that makes it possible to simply place and use portable media devices in a vehicle.

In order to accomplish the objects of the present invention, a car audio system includes: a car audio system main body that is mounted in a vehicle; a front panel that is disposed on the front of the car audio system main body and rotatably connected with the car audio system main body; and a stand that is provided on the rear of the front panel to place a portable media device.

At least one of a radio, a compact disc player, a DVD player, and a cassette player is provided in the car audio system main body, and an operating portion for operating the audio device provided in the car audio system main body and a display for checking the operation state are provided on the front of the front panel.

The car audio main body is provided with an expansion slot for connecting an external memory.

The stand has a terminal that is connected with the portable media device, and the expansion slot is connected to the terminal and connected to the portable media device through the terminal.

A shock absorbing means is interposed between the rear of the front panel and the front of the car audio system main body.

The shock absorbing means has a protrusion that protrudes from one of the rear of the front panel and the front of the car audio system main body, and an elastic body that is disposed on the other one, corresponding to the protrusion.

The stand includes: a base body that is mounted on the rear of the front panel, and has a protruding base at the lower portion and a terminal that is provided to be connected with the portable media device on the upper surface of the base; and a first jaw and a second jaw that are provided apart from each other on the front of the base body and nip and fix the portable media device therebetween.

The first jaw and the second jaw are movably mounted on the front of the base body and supported by a clamping spring.

A media device operating portion for operating the portable media device connected to the terminal is provided on the rear of the front panel.

The stand is rotatably mounted on the front panel to control the rotational position.

The stand includes a rotary shaft that protrudes from the rear of the base body arid has a plurality of spaced locking grooves on the outer circumference, and an elastic lock that protrudes from the inner circumference of a shaft hole formed in the rear of the front panel to fit the rotary shaft and is inserted in the locking grooves.

The front pane member is rotatably attached to the car audio main body by hinge members provided at both lower sides of the car audio main body, and the hinge member includes: a fixing link member that is provided at both front sides of the car audio main body; a fixing cam member that is fixed to the fixing link member and has inclined surfaces with cams protruding from both sides; a movable cam member that has a cam groove corresponding to the cam; a cam casing that is fixed to one side of the front panel member while accommodating the movable cam member movably therein; a spring that is disposed in the cam casino and elastically supports the movable cam; a shaft that passes through the fixing cam member and the movable cam member; and a retainer that retains the cam casing not to be separated by elastic force of the spring.

The present invention improves the occupant's feeling of satisfaction by simply placing portable media devices in a vehicle to easily use them.

The present invention improves the interior appearances of a vehicle when not using portable media devices, by selectively exposing a stand for placing portable media devices.

In particular, the present invention further improves the occupant's feeling of satisfaction by making it possible to sufficiently utilize various functions of PMPs even in a vehicle.

### BRIEF DESCRIPTION OF THE DRAWINGS

FIG. 1 is a perspective view showing the basic shape of the present invention;

FIG. 2 is a perspective view illustrating the operation of the present invention;

FIG. 3 is an exploded perspective view showing the hinge structure of the front panel of the present invention;

FIG. 4 is a cross-sectional view showing the hinge structure of the front panel of the present invention;

FIG. 5 is a cross-sectional view of an embodiment of the present invention;

FIG. 6 is a cross-sectional view of another embodiment of the present invention, and

FIGS. 7 and 8 are views illustrating an example of using the present invention.

### DETAILED DESCRIPTION OF THE PREFERRED EMBODIMENTS

A preferred embodiment of the present invention is described hereafter in detail with the accompanying drawings.

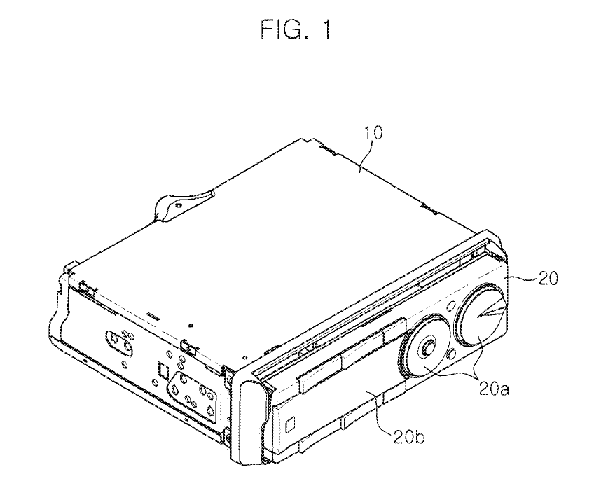

FIG. 1 is a perspective view showing the basic shape of the present invention, in which a front panel is disposed on the front of a main body, covering the front of the main body of a car audio system.

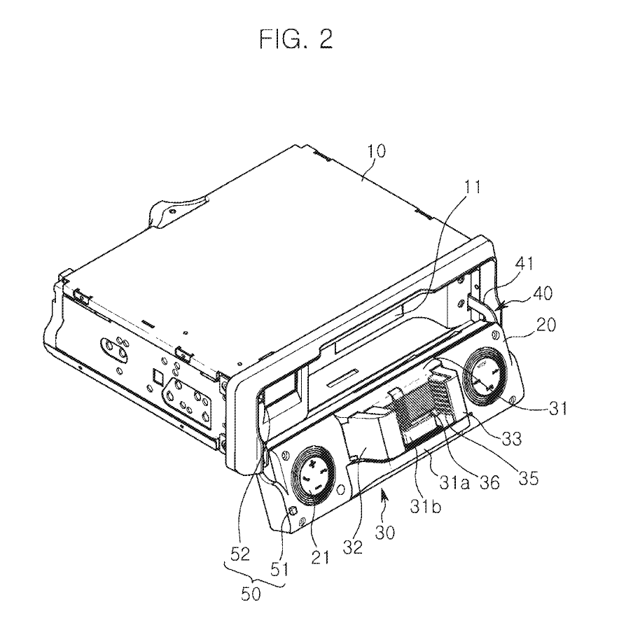

FIG. 2 is a perspective view illustrating the operation of the present invention, in which the front panel is rotated with the rear of the front panel facing the front of the main body such that the stand where a portable media device is placed is exposed.

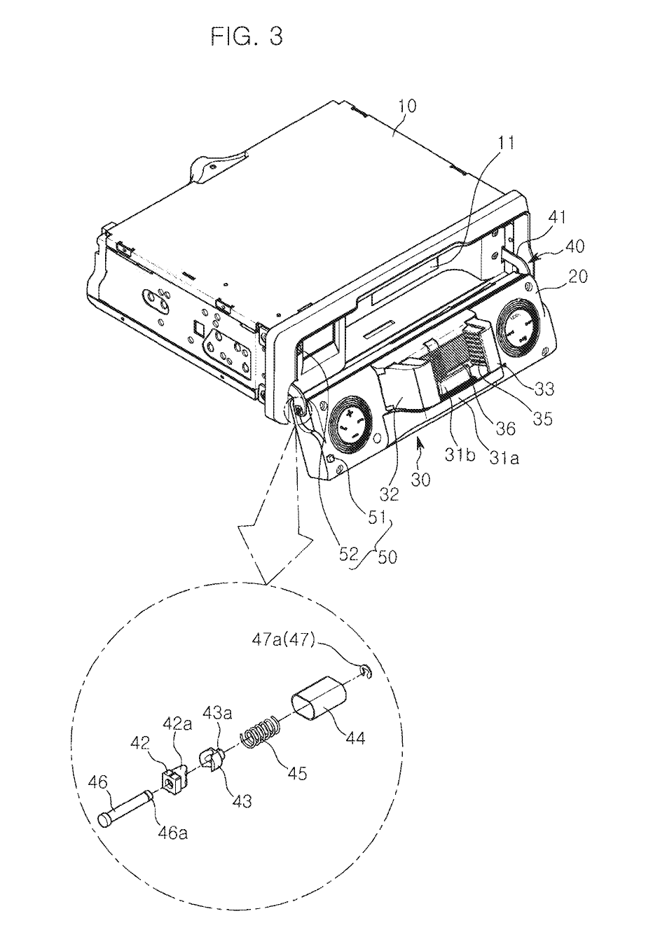

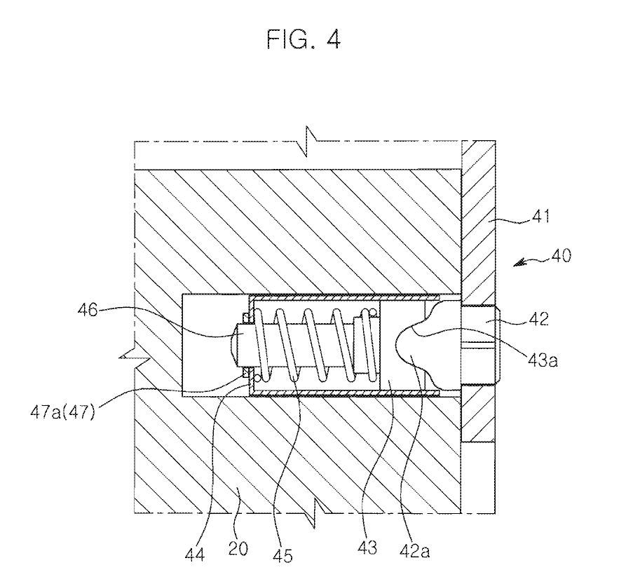

FIG. 3 is an exploded perspective view showing the hinge structure of the front panel of the present invention and FIG. 4 is a cross-sectional view showing the hinge structure of the front panel of the present invention, in which the hinge structure that fixes the front panel to an attached position on the front of the car audio main body member and a rotated open position.

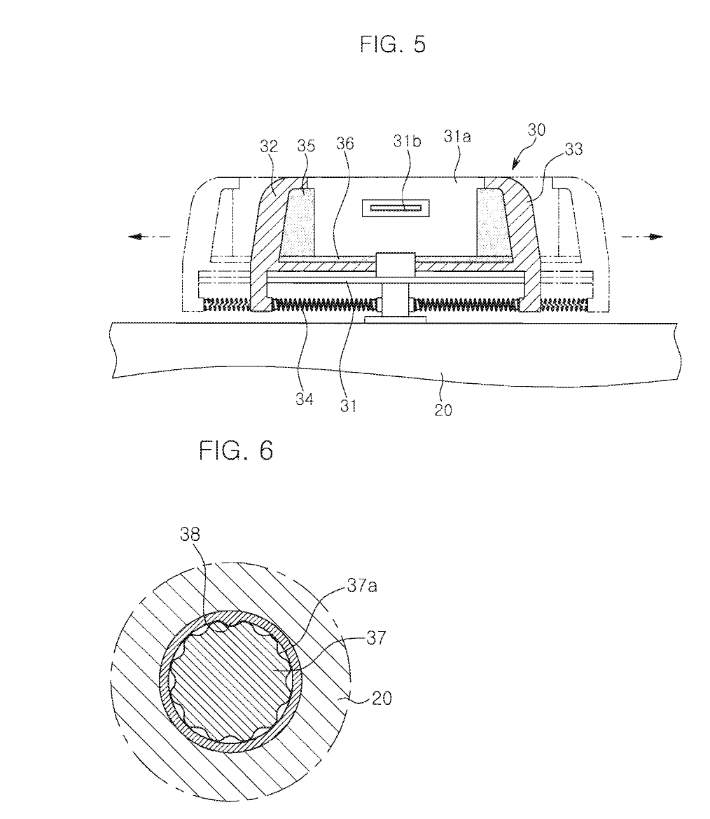

FIG. 5 is a cross-sectional view of an embodiment of the present invention, illustrating the structure of a stand where a portable media device is placed.

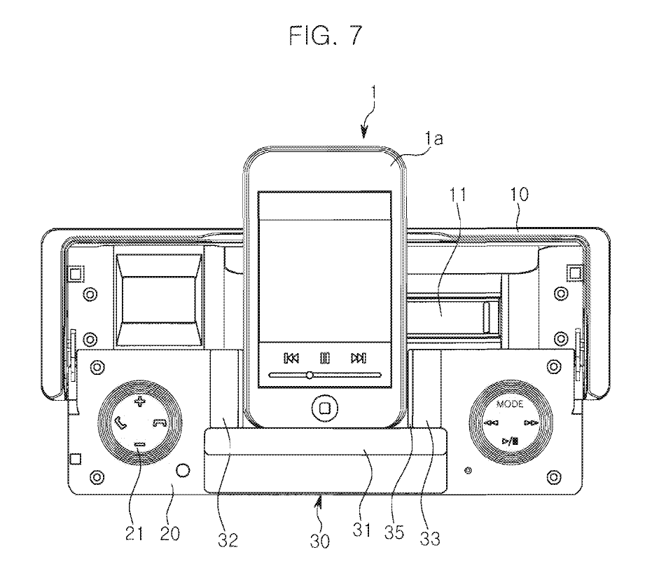

FIG. 6 is a cross-sectional view of another embodiment of the present invention, illustrating the rotational structure of a stand where a portable media device is placed.

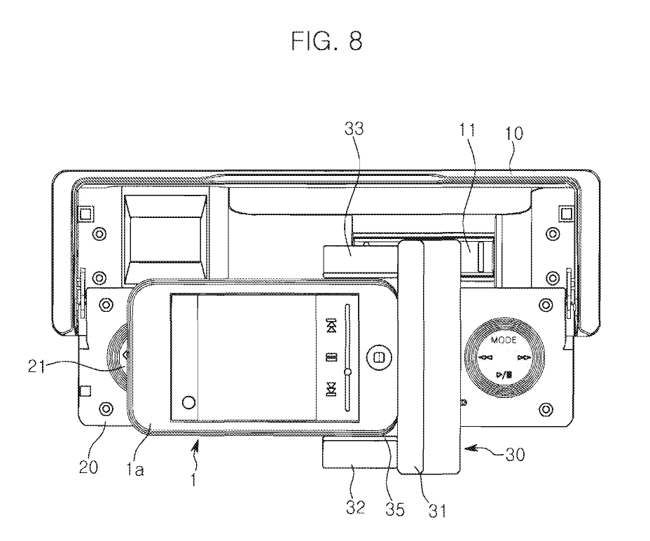

FIGS. 7 and 8 are views illustrating an example of using the present invention, in which a portable multimedia device is placed and used on a stand.

Hereinafter, as shown in FIGS. 1 and 2, a car audio system of the present invention includes a car audio main body 10 mounted inside a vehicle and a front panel 20 disposed on the front of the car audio main body 10 and covering the entire or a portion of the front of the car audio main body 10.

At least any one device of audio devices, such as a radio, a compact disc player, a DVD player, and a cassette player, is disposed inside the car audio main body 10 or the front panel 20, such that existing voice media, such as compact discs or cassette tapes, can be used.

Further, it is preferable that an operating portion 20a for operating the audio devices in the car audio main body or the front panel 20 and a display 20 For checking the operation state are provided on the front of the front panel 20.

It is preferable that the car audio main body 10 is provided with an expansion slot 11 to connect an external memory.

The expansion slot 11 includes a memory slot to directly insert and connect an USB (Universal Serial Bus) or a memory card and other connection terminals, and can be modified in various ways in accordance with the connection structures of the extension memories.

Further, it is preferable that the expansion slot 11 includes two or more memory connectors having different types of connection to use a plurality of various types of external memories.

It is preferable that the expansion slot 11 is connected with a portable media device 1 through a terminal 32b provided in a stand 30, which is described below, to connect and use an external memory with the portable media device 1.

The expansion slot 11 is provided to connect and use an external memory or the separate portable media device 1 which is not placed on the stand 30, and it should be understood that the external memory may implement the memory included in the portable media device 1.

On the other hand, the front pane member 20 is rotatably attached to the car audio main body 10 by hinge members 40 provided at both lower sides of the car audio main body 10.

The hinge member 40 includes: a fixing link member 41 that is provided at both front sides of the car audio main body 10; a fixing cam member 42 that is fixed to the fixing link member 41 and has inclined surfaces with cams 42a protruding from both sides; a movable cam member 43 that has a cam groove 43a corresponding to the cam 42a; a cam casino 44 that is fixed to one side of the front panel 20 while accommodating the movable cam member 43 movably therein; a spring 45 that is disposed in the cam casing 44 and elastically supports the movable cam 43; a shaft 46 that passes through the fixing cam member 42 and the movable cam member 43; and a retainer 47 that retains the cam casing 44 not to be separated by elastic force of the spring 45.

The shaft 46 protrudes through one end of the cam casing 44 through the fixing cam member 42, the movable cam member 43, and the cam casing 44 and a ring groove 46a is formed at the protruding end.

An e-ring 47a that is fitted in the ring groove 46a formed at the end of the shaft 46 and combines the shaft 46 with the cam casing 44 is basically used for the retainer 47, and further, it should be understood that any part that is connected to the end of the shaft 46 protruding through the end of the cam casing 44 and retains the combination of the shaft 46 with the cam casing can be used.

The hinge member 40 is a part that controls the position of the front panel, with the cam 42a of the fixing cam member 42 inserted in the cam groove 43a of the movable cam member 43, in which the position of the front panel 20 is changed by the cam 42a inserted in the cam groove 43a and rotating with both sides changing the positions in opposite directions.

The positional range of the front panel 20 is from a position where the front panel 20 is closed to overlap the front of the car audio main body 10 to a position where the front pane 20 rotates open such that the rear facing the front side and the front of the car audio main body 10 is exposed.

The front panel 20 is basically closed to cover the front of the car audio main body 10, and when predetermined force is applied to the front panel 20 covering the front of the car audio main body 10, the movable cam member 43 rotates about the shaft 46 while moving along the inclined surface of the cam 42a, such that the front panel, 20 is opened with the rear facing the front side.

When predetermined force or more is applied to the front panel 20 which is open to be closed, the movable cam member 43 rotates about the shaft 46 while moving along the inclined surfaces of the cam 42a in the opposite direction when it is opened, such that the front panel 20 is closed to overlap the front of the car audio main body 10.

That is, the front panel 20 is rotated by the hinge members 40 only when an occupant applies predetermined force or more.

Further, it is preferable that a shock absorbing means 50 is interposed between the rear of the front panel 20 and the front of the car audio main body 10 to absorb the shock generated when the front panel 20 is closed.

The shock absorbing means 50 includes a protrusion 51 that protrudes from any one of the rear of the front panel 20 and the front of the car audio main body 10 and an elastic body 52 that is disposed to correspond to the protrusion 51 at the other one.

The elastic body 52 can be made of any elastic material, including rubber and synthetic rubber.

That is, the shock absorbing means 50 absorbs the shock generated when the front pane 20 is closed to cover the front of the car main body 10 and prevents the front panel 20 from hitting on the front of the car audio main body 10, by hitting the protrusion 51 on the elastic body 52 in advance.

Meanwhile, the stand 30 where the portable medial device 1 is placed is provided on the rear of the front panel 20.

The stand 30 is provided on the rear of the front panel 20 and available when it is exposed to the front side and the front panel 20 is open.

The stand 30 includes: a base body 31 that is mounted on the rear of the front panel 20 and has a base 31a at the lower portion; and a first jaw 32 and a second jaw 33 that are disposed apart from each other on the front of the base body 31, and hold and fix the portable media device 1 therebetween.

It is preferable that any one of the first jaw 32 and the second jaw 33 is movable and a claming spring 34 that elastically supports the movable jaw to hold the portable media device 1 held between the jaws.

It is preferable that the first jaw 32 and the second law 33 are movably disposed on the front of the base body 31, supported by the clamping spring 34, and hold both sides of the portable media device 1 connected to a terminal 31b which is described below.

The first jaw 32 and the second jaw 33 can be adjusted in the gap therebetween and can held various sizes of portable media devices 1, and fixes the portable media devices 1 while applying uniform pressing force to both sides of the portable media devices 1 from the terminal 31b.

It is preferable for the first jaw 32 and the second jaw 33 to have a first elastic pad 35 on the contact surface with the portable media device 1.

Further, it is more preferable that a second elastic pad 36 that contacts with the rear of the portable media device 1 is provided on the front of the base body 31.

The first elastic pad 35 and the second elastic pad 36 firmly clamp the portable media device 1, which is pressed and fixed between the first jaw 32 and the second jaw 33 by the elastic force of the clamping spring 34, to be in close contact with the first jaw 32 and the second jaw 33, and also prevent the portable media device 1 from being broken or damaged by absorbing vibration of the vehicle which travels.

Further, it is preferable that the stand 30 further includes the terminal 31b that protrudes from the upper surface of the base 31a to be connected with the portable media device 1.

The terminal 31b includes a power terminal, connected to the terminal of the portable media device 1 to supply electric power, such that it can supply electric power to the portable medial device 1 to be charged in a vehicle, and the portable media device 1 can be used without using the charged electricity.

Further, the terminal 31b includes a control terminal to control the operation of the portable media device 1 connected by a separate media device operating unit 21, such that an occupant can operate the portable media device 1 placed on the stand 30 using the separate medial device operating unit 21.

The medial device operating unit 21 is basically provided on the rear of the front panel 20 and may be mounted on the steering wheel such that the driver can hold and operate it while driving.

On the other hand, it is preferable that the stand 30 is rotatably mounted on the front panel 20 to control the rotation position.

The stand 30 further includes a rotary shaft 37 that protrudes from the rear of the base body 31 and has a plurality of spaced locking grooves 37a on the outer circumference; and an elastic lock 38a that protrudes from the inner circumference of a shaft hole formed in the rear of the front panel 20 to fit the rotary shaft 37 and is inserted In the locking grooves 37a, such that it is rotatably combined with the front panel 20 and the rotational position is controlled.

That is, the stand 30 rotates about the rotary shaft 37 and the rotational position is fixed when the lock 38 is inserted in the locking grooves 37a.

Further, when force that separates the elastic lock 38 from the locking grooves 37a is applied to the stand 30 to be rotated, the stand 30 rotates with repeated insertion of the elastic lock 38 separated from the locking groove 37a into the other locking grooves 37a, such that the position is fixed to a rotational angle in accordance with the position of the elastic lock 38 inserted in the locking grooves 37a.

Other than the above structure, the stand 30 can be modified to have any structure that can rotate the stand 30 while fixing/moving it to/from the rotational positions, and it should be understood that this is included in the configuration of the present invention.

The car audio system of the present invention is used by rotating the front panel 20 such that the stand 30 on the rear of the front panel 20 is exposed, as shown in FIG. 7, when placing the portable media device 1, such as a PMP 1a (Portable Multimedia Player), in the vehicle.

The OMP 1a is clamped between the first jaw 32 and the second jaw 33 elastically supported by the clamping spring 34 and used by being connected to the terminal 31b of the base 31a of the stand 30.

Further, the stand 30, as shown in FIG. 8, may be rotated such that the PMP 1a is transversely positioned. This is for an occupant to comfortably watch a video on the PMP 1a by transversely rotating the PMP 1a, and it is possible for the occupant to rotate the stand 30 to adjust the PMP 1a at a desired angle to comfortably view.

The present invention is not limited to the above embodiments and can be modified in various ways without departing from the scope of the present invention, and it should be understood that the modifications are included in the spirit of the present invention.

What is claimed is:

1. A car audio system comprising:
a car audio main body that is mounted in a vehicle;
a front panel that is disposed on the front of the car audio system main body and rotatably connected with the car audio main body; and
a stand that is provided on the rear of the front panel to place a portable media device.

2. The car audio system according to claim 1, wherein at least one of a radio, a compact disc player, a DVD player, and a cassette player is provided in the car audio main body, and
an operating portion for operating the audio device provided in the car audio main body and a display for checking the operational state are provided on the front of the front panel.

3. The car audio system according to claim 1, wherein the car audio system is provided with an expansion slot for connecting an external memory.

4. The car audio system according to claim 3, wherein the stand has a terminal that is connected with the portable media device, and
the expansion slot is connected to the terminal and connected to the portable media device through the terminal.

5 The car audio system according to claim 1, wherein a shock absorbing means is interposed between the rear of the front panel and the front of the car audio main body.

6. The car audio system according to claim 5, wherein the shock absorbing means has a protrusion that protrudes from one of the rear of the front panel and the front of the car audio main body, and an elastic body that is disposed on the other one, corresponding to the protrusion.

7. The car audio system according to claim 1, wherein the stand includes:
a base body that is mounted on the rear of the front panel, and has a protruding base at the lower portion and a terminal that is provided to be connected width the portable media device on the upper surface of the base; and
a first jaw and a second jaw that are provided apart from each other on the front of the base body and held and fix the portable media device therebetween.

8. The car audio system according to claim 7, wherein the first jaw and the second jaw are movably mounted on the front of the base body and supported by a clamping spring.

9. The car audio system according to claim 7, wherein a media device operating portion for operating the portable media device connected to the terminal is provided on the rear of the front panel.

10. The car audio system according to claim 7, wherein the stand is rotatably mounted on the front panel to control the rotational position.

11. The car audio system according to claim 10, wherein the stand includes a rotary shaft that protrudes from the rear of the base body and has a plurality of spaced locking grooves on the outer circumference, and
an elastic lock that protrudes from the inner circumference of a shaft hole formed in the rear of the front panel to fit the rotary shaft and is inserted in the locking grooves.

12. The car audio system according to claim 1, wherein the front pane member is rotatably attached to the car audio main body by hinge members provided at both lower sides of the car audio main body, and
the hinge member includes:
a fixing link member that is provided at both front sides of the car audio main body;
a fixing cam member that is fixed to the fixing link member and has inclined surfaces with cams protruding from both sides;
a movable cam member that has a cam groove corresponding to the cam;
a cam casing that is fixed to one side of the front panel member while accommodating the movable cam member movably therein;
a spring that is disposed in the cam casing and elastically supports the movable cam;
a shaft that passes through the fixing cam member and the movable cam member; and
a retainer that retains the cam casing not to be separated by elastic force of the spring.
